(19) United States
(12) Patent Application Publication
(10) Pub. No.: US 2014/0072761 A1
(43) Pub. Date: Mar. 13, 2014

(54) PLATE-SHAPED CASING MEMBER AND INSERT INJECTION MOLDING METHOD FOR THE SAME

(71) Applicant: PANASONIC CORPORATION, Osaka (JP)

(72) Inventors: Yoshihiro KAWADA, Osaka (JP); Kenichi SHINDO, Osaka (JP); Ryo YONEZAWA, Kyoto (JP); Yoshinari MATSUYAMA, Osaka (JP); Hirofumi SASAKI, Hyogo (JP)

(73) Assignee: PANASONIC CORPORATION, Osaka (JP)

(21) Appl. No.: 13/771,406

(22) Filed: Feb. 20, 2013

(30) Foreign Application Priority Data
Sep. 7, 2012 (JP) 2012-197603

(51) Int. Cl. H05K 5/02; B29C 45/14

(52) U.S. Cl. CPC H05K 5/02; B29C 45/14811
USPC 428/138; 264/273

(57) ABSTRACT

A plate-shaped casing member includes: a first member made of a metal material, the first member including a through hole, a first half-through hole having an opening in a first main-surface side around the through hole, and a second half-through hole having an opening in a second main-surface side around the through hole; and a second member made of a material, the second member extending over the first half-through hole, the through hole, and the second half-through hole in the first member, and the second member being bonded to the first member.

### BACKGROUND

1. Technical Field

The present disclosure relates to a plate-shaped casing member including a metal member and a resin member which are bonded to each other in a planar direction. The present disclosure also relates to an insert injection molding method for the same.

2. Background Art

In some cases, casing members for laptop personal computers are made of magnesium alloys, for realizing thickness reduction and weight reduction thereof. Further, as methods for fabricating insert-molded articles formed from combinations of magnesium alloys and resin materials, there have been known insert injection molding methods including: performing insert molding in such a way as to cover a metal plate at its entire surface and its entire outer peripheral surface with a resin plate; and forming flange portions from the resin having gone around the rear-surface side through fixing holes in the metal plate such that the flange portions are larger than the fixing holes (refer to Japanese Patent Laid-Open Publication No. 2010-718, for example).

With the aforementioned insert injection molding method, the flange portions larger than the fixing holes are formed from the resin having gone around the rear-surface side through the fixing holes in the metal plate. However, in the event of shrinkages of the resin, gaps are induced between the flange portions and the fixing holes in the metal plate, which has raised the possibility of disengagement of the resin from the front-surface side. Furthermore, resin injection holes are also formed to have tapered shapes in order to prevent disengagement of the resin. However, even in this case, it may be impossible to provide the effect of preventing the disengagement, depending on the degree of the shrinkage of the resin.

### SUMMARY OF THE INVENTION

An object of the present disclosure is to provide a plate-shaped casing member having an improved strength for bonding a metal material and a resin material to each other.

A plate-shaped casing member according to the present disclosure includes:

a first member made of a metal material, the first member including a through hole, a first half-through hole having an opening in a first main-surface side around the through hole, and a second half-through hole having an opening in a second main-surface side around the through hole; and

a second member made of a material, the second member extending over the first half-through hole, the through hole and the second half-through hole in the first member, and the second member being bonded to the first member.

The plate-shaped casing member according to the present disclosure includes the second portion extending over the first half-through hole, the through hole, and the second half-through hole in the first member. Therefore, the second member is prevented from being disengaged therefrom either toward the first main-surface side or toward the second main-surface side of a through hole 3 in the first member, thereby maintaining the bonding between the first member and the second member. Further, even in the event of the occurrence of distortions in the first member or the second member, it is possible to maintain the bonding.

### BRIEF DESCRIPTION OF THE DRAWINGS

The present invention will become readily understood from the following description of preferred embodiments thereof made with reference to the accompanying drawings, in which like parts are designated by like reference numeral and in which:

FIG. 1 is a plan view illustrating a plate-shaped casing member according to a first embodiment, at its rear surface;

FIG. 2 is a cross-sectional view illustrating the cross-sectional structure of the same, taken along the direction of line A-A in FIG. 1;

FIG. 3 is a partially-enlarged cross-sectional view of a bonding portion B between a first member and a second member in FIG. 2;

FIG. 4 is a partial cross-sectional view illustrating a state where the first member has been inserted on a first die, and the first die and a second die have been clamped to each other, in an insert injection molding method for the plate-shaped casing member according to the first embodiment;

FIG. 5 is a partial cross-sectional view of the plate-shaped casing member provided by injecting a material into a cavity portion, then cooling and solidifying the material and, thereafter, opening the dies, in the state where the first die and the second die have been clamped to each other in FIG. 4;

FIG. 6 is a partial cross-sectional view of a plate-shaped casing member according to a first modification example, which corresponds to FIG. 5;

FIG. 7 is a cross-sectional view illustrating a cross-sectional structure of a plate-shaped casing member according to a second modification example, taken along the direction of line A-A in FIG. 1;

FIG. 8 is a partially-enlarged cross-sectional view of a bonding portion “C” between a first member and a second member in FIG. 7;

FIG. 9 is a partial cross-sectional view illustrating a state where the first member has been inserted on a first die, and the first die and a second die have been clamped to each other, in an insert injection molding method for the plate-shaped casing member according to the second modification example;

FIG. 10 is a partial cross-sectional view of the plate-shaped casing member according to the second modification example which has been provided by injecting a material into a cavity portion, then cooling and solidifying the material and, thereafter, opening the dies, in the state where the first die and the second die have been clamped to each other in FIG. 9;

FIG. 11 is a plan view illustrating the plate-shaped casing member in FIG. 1, at its front surface;

FIG. 12 is a perspective view illustrating the plate-shaped casing member in FIG. 11 at its front surface;

FIG. 13 is a perspective view illustrating an external appearance of a laptop personal computer including the plate-shaped casing member according to the first embodiment in its display portion, in a state where the display portion is closed; and

FIG. 14 is a perspective view illustrating an external appearance of the laptop personal computer including the plate-shaped casing member according to the first embodiment in its display portion, in a state where the display portion is opened.

### DETAILED DESCRIPTION OF EMBODIMENTS

A plate-shaped casing member in a first aspect of the present disclosure includes:

a first member made of a metal material, the first member including a through hole, a first half-through hole having an opening in a first main-surface side around the through hole, and a second half-through hole having an opening in a second main-surface side around the through hole; and

a second member made of a material, the second member extending over the first half-through hole, the through hole, and the second half-through hole in the first member, and the second member being bonded to the first member.

In a second aspect, in the plate-shaped casing member in the aforementioned first aspect, the second member may extend in such a way as to intersect the through hole in the first member, with an inclination in a thickness direction.

In a third aspect, in the plate-shaped casing member in the aforementioned first aspect, the second member may include a going-around portion which extends from the second half-through hole in the first member and goes around the first member at a rear-surface portion of the second half-through hole.

In a fourth aspect, in the plate-shaped casing member in the aforementioned third aspect, the going-around portion in the second member may goes around and extends to a tapered surface in the rear-surface portion of the second half-through portion in the first member.

In a fifth aspect, in the plate-shaped casing member in the aforementioned first aspect, the first member may have a plate-shaped portion, and the through hole in the first member may have a depth which is twice the thickness of the plate-shaped portion or less.

In a sixth aspect, in the plate-shaped casing member in the aforementioned first aspect, the metal material may be a magnesium alloy.

In a seventh aspect, in the plate-shaped casing member in the aforementioned first aspect, the material may be a resin material.

An insert injection molding method for a plate-shaped casing member in an eighth aspect includes:

preparing an injection molding die including a first die and a second die which can be coupled to and separated from the first die, wherein, in the first die, a first member made of a metal material has been inserted, the first member includes a through hole, a first half-through hole having an opening in a first main-surface side around the through hole, and a second half-through hole having an opening in a second main-surface side around the through hole, and the second die includes surfaces to be faced to the through hole and the first half-through hole or the second half-through hole in the first member inserted in the first die, when the second die is clamped to the first die;

clamping the first die and the second die to each other;

injecting a material into a cavity portion formed between the second die and the first member inserted on the first die, and cooling and solidifying the material, thereby forming a second member made of the material, wherein the material extends over the first half-through hole, the through hole and the second half-through hole in the first member; and

opening the first die and the second die, and extracting the plate-shaped casing member constituted by the inserted first member and the second member bonded to the first member.

Hereinafter, an embodiment will be described in detail, with reference to the drawings, appropriately. However, descriptions in detail more than necessary may be omitted. For example, matters which have been already well known may not be described in detail, and substantially the same structures may not be described redundantly. This is for avoiding the following descriptions from being unnecessarily redundant for allowing those skilled in the art to easily understand them.

Further, the present inventors give the accompanying drawings and the following descriptions for allowing those skilled in the art to sufficiently understand the present disclosure, and the subject matter defined in the claims is not intended to be restricted thereby. Further, in the drawings, like reference characters refer to substantially the same members.

### First Embodiment

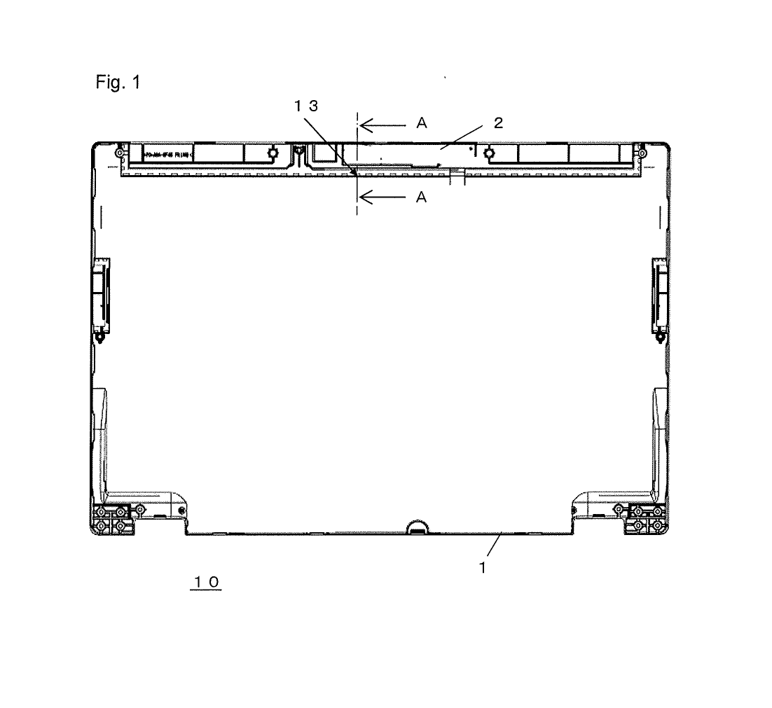

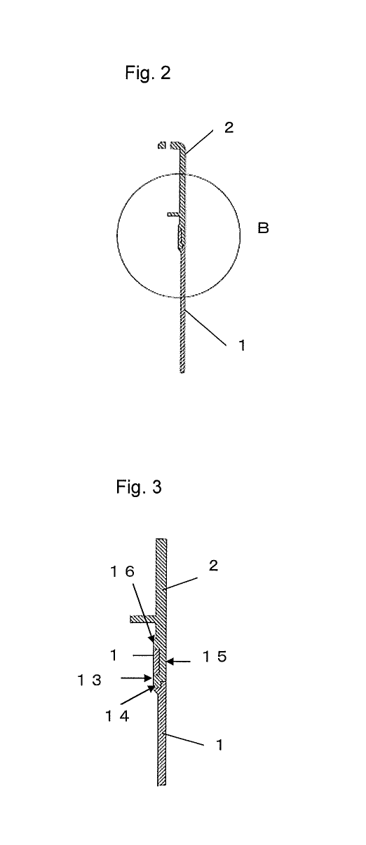

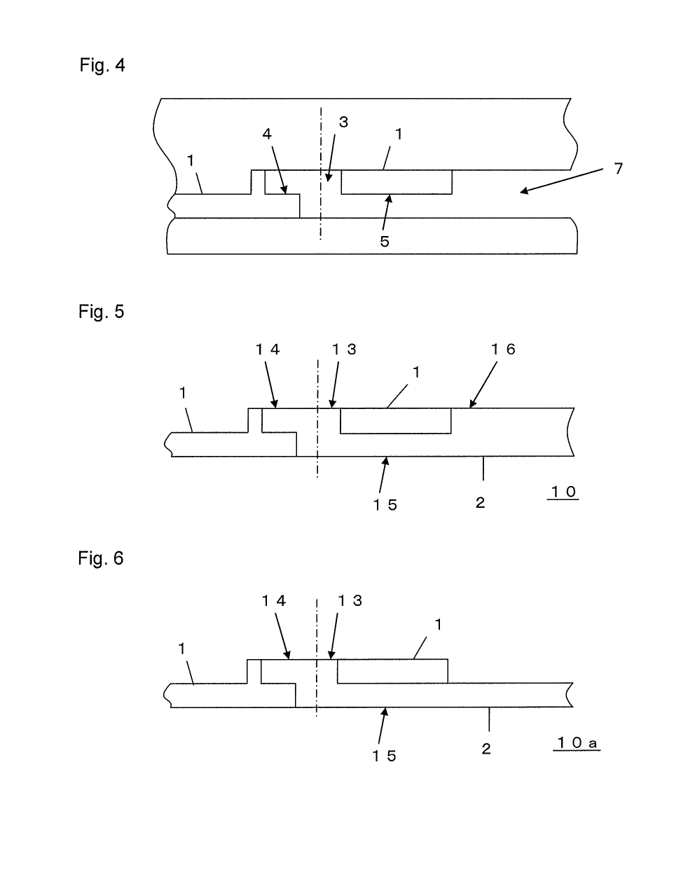

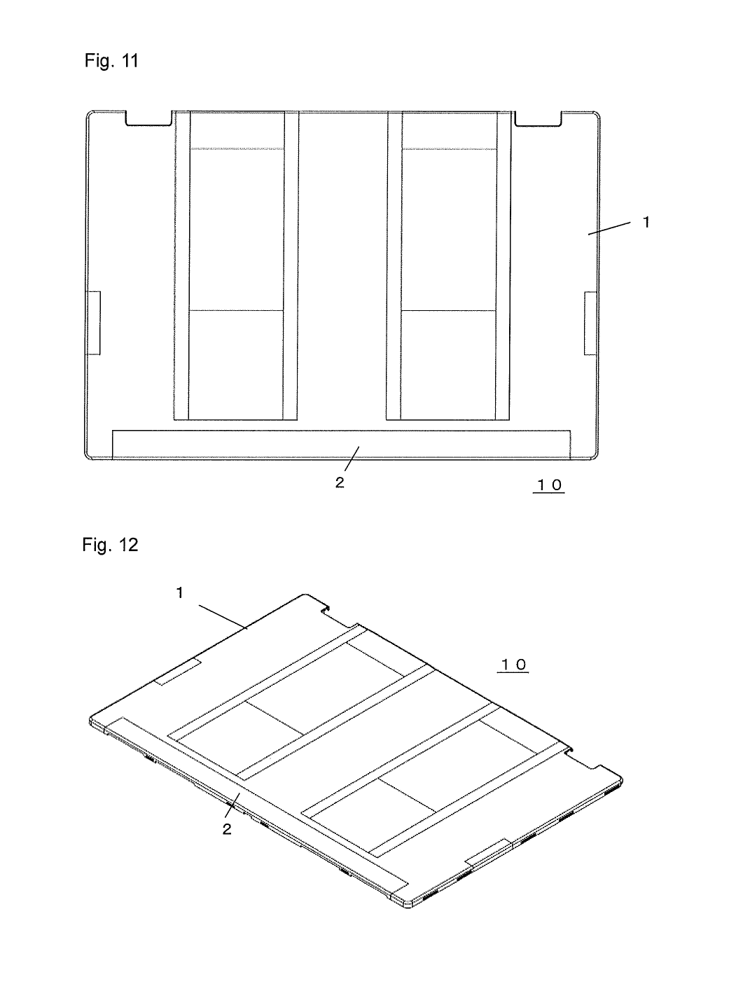

FIG. 1 is a plan view illustrating a plate-shaped casing member 10 according to a first embodiment, at its rear surface. FIG. 2 is a cross-sectional view illustrating the cross-sectional structure of the same, taken along the direction of line A-A in FIG. 1. FIG. 3 is a partially-enlarged cross-sectional view of a bonding portion B between a first member 1 and a second member 2 in FIG. 2. FIG. 4 is a partial cross-sectional view illustrating a state where the first member 1 has been inserted on a first die 32, and the first die 32 and a second die 34 have been clamped to each other, in an insert injection molding method for the plate-shaped casing member 10 according to the first embodiment. FIG. 11 is a plan view illustrating the plate-shaped casing member 10 in FIG. 1, at its front surface. FIG. 12 is a perspective view illustrating the plate-shaped casing member 10 in FIG. 11 at its front surface.

The plate-shaped casing member 10 includes two members bonded to each other. These two members are the first member 1 made of a metal material, and the second member 2 made of a material, which is a resin material or the like. In the example illustrated in FIG. 1, the plate-shaped casing member 10 includes the first member 1 having a plate shape which occupies a major part of the plate-shaped casing member 10, and the plate-shaped casing member 10 includes the second member 2 bonded to the first member 1 at a single side thereof. In the bonding portion, the first member 1 includes a through hole 3, a first half-through hole 4 having an opening in a first main-surface side around the through hole 3, and a second half-through hole 5 having an opening in a second main-surface side around the through hole 3. Further, the second member 2 extends over the first half-through hole 4, the through hole 3, and the second half-through hole 5 in the first member 1. More specifically, in the second member 2, the portion embedded in the through hole 3 forms a through-hole portion 13, the portion embedded in the first half-through hole forms a first half-through-hole portion 14, and the portion embedded in the second half-through hole 5 forms a second half-through-hole portion 15. In the second member 2, the first half-through-hole portion 14, the through-hole portion 13, and the second half-through-hole portion 15 extend in such a way as to intersect the through hole 3 in the first member 1, with inclinations in the thickness direction. In other words, the first half-through-hole portion 14 in the first main-surface side in the second member 2 and the second half-through-hole portion 15 in the second main-surface side are provided in such a way as to sandwich the through hole 3 in the first member 1 therebetween. Therefore, even in the event of the occurrence of a gap between the second member 2 and the through hole 3 in the first member 1 due to shrinkages and the like, the second member 2 is prevented from being disengaged therefrom either toward the first main-surface side or toward the second main-surface side of the through hole 3 in the first member 1, thereby maintaining the bonding between the first member 1 and the second member 2. Further, even in the event of the occurrence of distortions in the first member 1 or the second member 2, it is possible to maintain the bonding in the same manner.

Further, the plate-shaped casing member 10 may have various structures for improving the strength, decorations for providing aesthetic appearances, and the like, in its rear surface (FIG. 1) and its front surface (FIGS. 11 and 12).

Hereinafter, the components constituting the plate-shaped casing member 10 will be described.

### As to the First Member:

The first member 1 is made of a metal material. As the metal material, it is possible to use a magnesium alloy, for example.

Further, the first member 1 includes a plate-shaped portion occupying a major part thereof, and a portion bonded to the second member 2. The first member 1 includes the through hole 3, the first half-through hole 4 having an opening in the first main-surface side around the through hole 3, and the second half-through hole 5 having an opening in the second main-surface side around the through hole 3, in its portion bonded to the second member 2. Further, the through hole 3 in the first member 1 may have a depth which is twice the thickness of the plate-shaped portion or less. The first half-through hole 4 and the second half-through hole 5 are different from each other, in that they have the opening in the first main-surface side and the opening in the second main-surface side, respectively. Further, in FIGS. 3, 5, 6, 8 and 10, the first half-through hole 4 and the second half-through hole 5 are placed in the opposite directions from each other with respect to the center of the through hole 3. Thus, it can be controlled that the bonding portion between the first member 1 and the second member 2 has a thickness smaller than twice the thickness of the plate-shaped portion of the first member 1. However, the placement of the first half-through hole 4 and the second half-through hole 5 is not limited to that in which they are placed in the opposite directions from each other with respect to the center of the through hole 3 as described above. For example, the first half-through hole 4 and the second half-through hole 5 may be placed in substantially the same direction with respect to the center of the through hole 3.

### As to the Second Member

The second member 2 is made of a resin material, for example. Further, the second member 2 may be also made of other materials than resin materials. For example, the second member 2 may be made of any metal material having a lower melting point than that of the metal material forming the first member 1.

The second member 2 extends over the first half-through hole 4, the through hole 3, and the second half-through hole 5 in the first member 1. Further, as illustrated in FIGS. 2 and 3, the second member 2 may have a going-around portion 16 which extends from the second half-through hole 5 in the first member 1 and goes around the first member 1 at the rear-surface portion of the second half-through hole 5. Further, the going-around portion 16 in the second member 2 may also extend and go around a tapered surface 6 in the rear-surface portion of the second half-through portion 15 in the first member 1.

### As to the Insert Injection Molding Method:

FIG. 4 is a partial cross-sectional view illustrating a state where the first member 1 has been inserted on the first die 32, and the first die 32 and the second die 34 have been clamped to each other, in the insert injection molding method for the plate-shaped casing member 10 according to the first embodiment. FIG. 5 is a partial cross-sectional view of the plate-shaped casing member 10 provided by injecting the material into a cavity portion 7, then cooling and solidifying the material and, thereafter, opening the dies, in the state where the first die 32 and the second die 34 have been clamped to each other in FIG. 4.

The plate-shaped casing member constituted by the first member and the second member which are bonded to each other can be provided through the insert injection molding method which will be described later.

(a) An injection molding die is prepared, wherein the injection molding die includes the first die 32, and the second die 34 which can be coupled to and separated from the first die 32. In the first die 32, the first member 1 made of the metal material has been inserted, wherein the first member 1 includes the through hole 3, the first half-through hole 4 having an opening in the first main-surface side around the through hole 3, and the second half-through hole 5 having an opening in the second main-surface side around the through hole 3. In this case, preferably, the first member 1 is pressed to the surface of the first die 32 through suction and the like, for example. The second die 34 includes surfaces to be faced to the through hole 3 and the first half-through hole 4 or the second half-through hole 5 in the first member 1 having been inserted on the first die 32, when the second die 34 has been clamped to the first die 32.

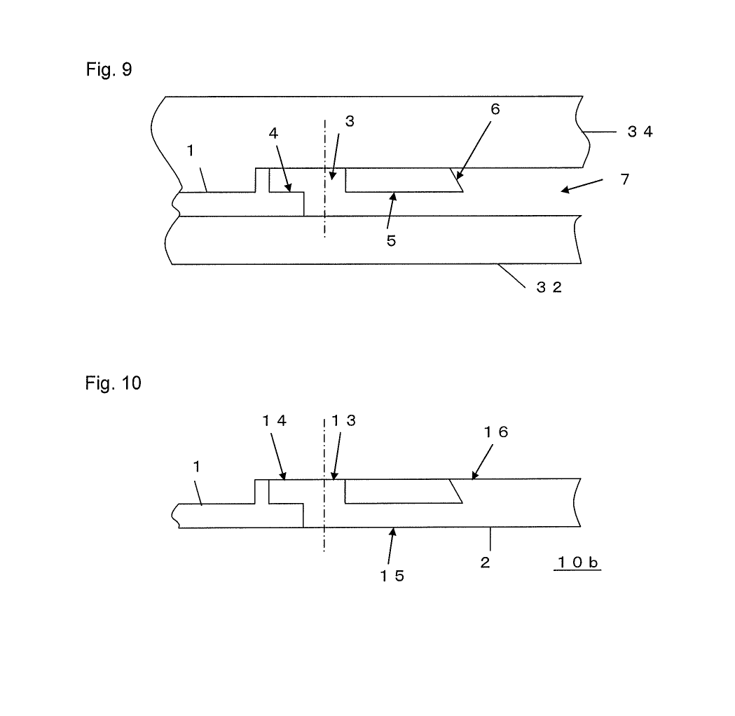

(b) The first die 32 and the second die 34 are clamped to each other (FIGS. 4 and 9).

(c) The material is injected into the cavity portion 7 formed between the second die 34 and the first member 1 inserted on the first die 32, and the material is cooled and solidified. This results in formation of the second member 2 which is made of the material and extends over the first half-through hole 4, the through hole 3, and the second half-through hole 5 in the first member 1.

(d) The first die 32 and the second die 34 are opened, and the plate-shaped casing member 10 is extracted therefrom, wherein the plate-shaped casing member 10 is constituted by the inserted first member 1 and the second member 2 bonded to the first member 1 (FIGS. 5, 6 and 10).

In the aforementioned manner, the plate-shaped casing member 10 can be provided.

### Effects and the Like

Further, the present inventors have recognized that the casing member 10 provided through the aforementioned insert injection molding method can provide the effect of preventing the first member 1 and the second member 2 from being separated from each other. Some hypotheses can be presumed, regarding behaviors of stresses of when the injected resin material is cooled and solidified, in order to provide the effect. As a available hypothesis, a mechanism as follows is presumed. It is presumed that, out of the resin material flowed into the through hole 3 and the first and second half-through holes 4 and 5 in the first member, the resin material flowed into the first and second half-through holes 4 and 5 is cooled to be solidified, faster than the through hole 3. Further, it is presumed that, thereafter, the resin material embedded in the through hole 3 is solidified and, at this time, the portions around the through hole 3 have been previously cooled to be solidified, which induces less forces exerted thereon in other directions than the thickness direction, thereby inducing less distortions. Accordingly, the molded casing member 10 has less distortions therein, thereby providing the effect of preventing the members from being separated from each other.

### First Modification Example

FIG. 6 is a partial cross-sectional view of a plate-shaped casing member 10a according to the first modification example. The plate-shaped casing member 10a according to the first modification example is different from the plate-shaped casing member 10 in FIG. 5, in that there is no going-around portion 16. In this case, it is possible to fabricate the plate-shaped casing member, more simply. Further, in cases where it is necessary to provide a sufficient strength at the bonding, it is preferable to provide a going-around portion 16 as in the plate-shaped casing member 10 in FIG. 5.

### Second Modification Example

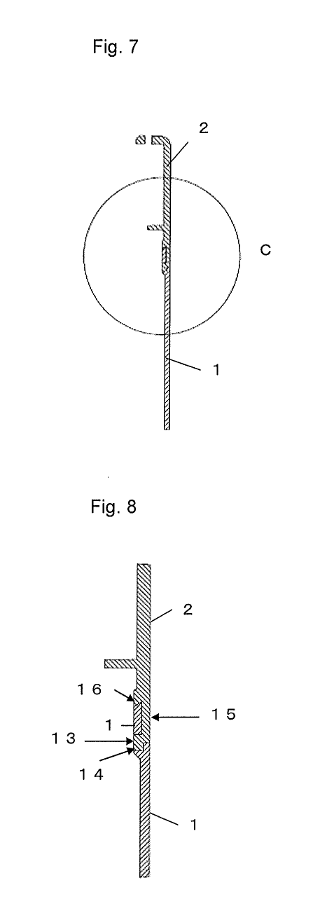

FIG. 7 is a cross-sectional view illustrating a cross-sectional structure of a plate-shaped casing member 10b according to a second modification example, taken along the direction of line A-A in FIG. 1. FIG. 8 is a partially-enlarged cross-sectional view of a bonding portion C between a first member 1 and a second member 2 in FIG. 7. FIG. 9 is a partial cross-sectional view illustrating a state where the first member 1 has been inserted on a first die 32, and the first die 32 and a second die 34 have been clamped to each other, in an insert injection molding method for the plate-shaped casing member 10b according to the second modification example. FIG. 10 is a partial cross-sectional view of the plate-shaped casing member 10b according to the second modification example which has been provided by injecting a material into a cavity portion 9, then cooling and solidifying the material and, thereafter, opening the dies, in the state where the first die 32 and the second die 34 have been clamped to each other in FIG. 9.

The plate-shaped casing member 10b according to the second modification example is different from the plate-shaped casing member 10 in FIG. 5, in that a going-around portion 16 goes around a tapered surface 6 in the first member 1. Since the going-around portion 16 is formed to go around the tapered surface 6, the first member 1 and the second member 2 are further prevented from being disengaged from each other, at the bonding therebetween.

### As to Personal Computer:

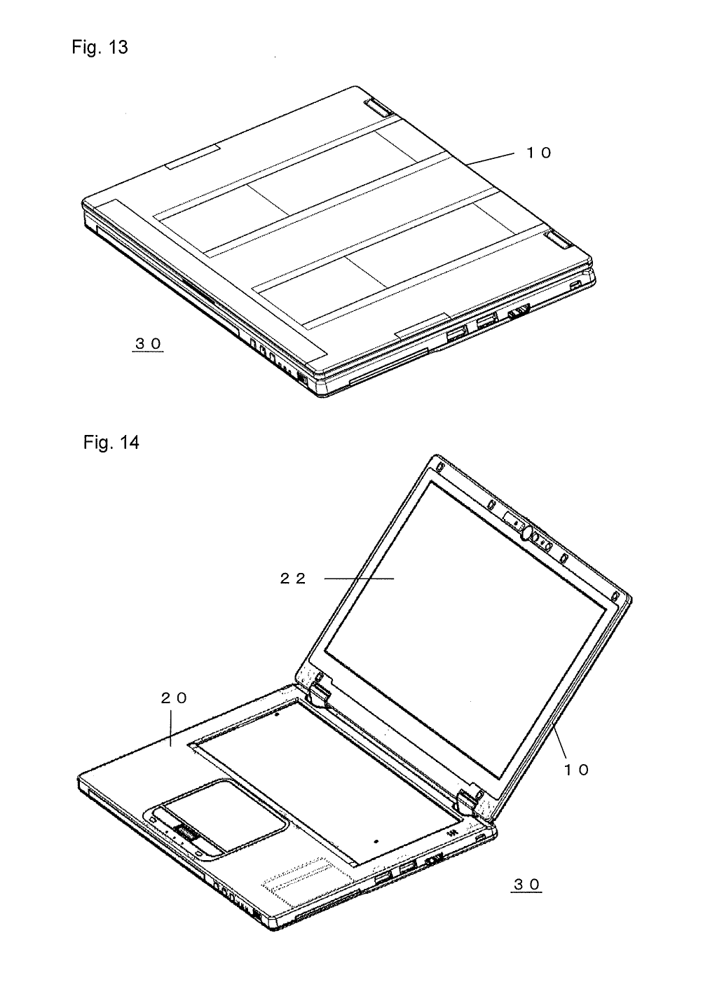

FIG. 13 is a perspective view illustrating an external appearance of a laptop personal computer 30 including the plate-shaped casing member 10 according to the first embodiment in its display portion, in a state where the display portion is closed. FIG. 14 is a perspective view illustrating an external appearance of the laptop personal computer 30 including the plate-shaped casing member 10 according to the first embodiment in its display portion, in a state where the display portion is opened.

The laptop personal computer 30 includes the plate-shaped casing member (an upper casing) 10 employed in the display portion which holds a display 22, and includes a lower casing 20. The plate-shaped casing member 10 as the upper casing has a higher strength for bonding the first member 1 and the second member 2 to each other, which can improve the strength of the laptop personal computer 30.

As described above, an embodiment has been described as an example of the techniques according to the present disclosure. Thus, the accompanying drawings and the detailed description have been given.

Accordingly, the constituents described in the accompanying drawings and the detailed description may also include constituents which are unnecessary for overcoming the problems, in order to exemplify the aforementioned techniques, as well as constituents necessary for overcoming the problems. Therefore, such unnecessary constituents should not be immediately determined to be necessary, for the reason that these unnecessary constituents are described in the accompanying drawings and the detailed description.

Further, the aforementioned embodiment is merely for exemplifying the techniques according to the present disclosure and, therefore, various changes, replacements, additions, omissions and the like can be made thereto within the scope of the claims and scopes equivalent thereto.

The present disclosure can be applied to plate-shaped casing members including a metal member and a resin member which are bonded to each other in a planar direction. More specifically, the present disclosure can be applied to plate-shaped casing members for use in electronic apparatuses such as laptop personal computers.

What is claimed is:

1. A plate-shaped casing member comprising:
a first member made of a metal material, the first member including a through hole, a first half-through hole having an opening in a first main-surface side around the through hole, and a second half-through hole having an opening in a second main-surface side around the through hole; and
a second member made of a material, the second member extending over the first half-through hole, the through hole, and the second half-through hole in the first member, and the second member being bonded to the first member.

2. The plate-shaped casing member according to claim 1, wherein
the second member extends in such a way as to intersect the through hole in the first member, with an inclination in a thickness direction.

3. The plate-shaped casing member according to claim 1, wherein
the second member includes a going-around portion which extends from the second half-through hole in the first member and goes around the first member at a rear-surface portion of the second half-through hole.

4. The plate-shaped casing member according to claim 3, wherein
the going-around portion in the second member goes around and extends to a tapered surface in the rear-surface portion of the second half-through portion in the first member.

5. The plate-shaped casing member according to claim 1, wherein
the first member has a plate-shaped portion, and the through hole in the first member has a depth which is twice the thickness of the plate-shaped portion or less.

6. The plate-shaped casing member according to claim 1, wherein
the metal material is a magnesium alloy.

7. The plate-shaped casing member according to claim 1, wherein
the second member is a resin material.

8. An insert injection molding method for a plate-shaped casing member, comprising:
preparing an injection molding die including a first die and a second die which can be coupled to and separated from the first die, wherein, in the first die, a first member made of a metal material has been inserted, the first member includes a through hole, a first half-through hole having an opening in a first main-surface side around the through hole, and a second half-through hole having an opening in a second main-surface side around the through hole, and the second die includes surfaces to be faced to the through hole and the first half-through hole or the second half-through hole in the first member inserted in the first die, when the second die is clamped to the first die;
clamping the first die and the second die to each other;
injecting a material into a cavity portion formed between the second die and the first member inserted on the first die, and cooling and solidifying the material, to form a second member made of the material, the material extending over the first half-through hole, the through hole, and the second half-through hole in the first member; and
opening the first die and the second die, and extracting the plate-shaped casing member comprising the inserted first member and the second member bonded to the first member.
